(19) United States
(12) Patent Application Publication
(10) Pub. No.: US 2009/0239383 A1
(43) Pub. Date: Sep. 24, 2009

(54) MANUFACTURING METHOD OF SEMICONDUCTOR DEVICE

(75) Inventors: Youichirou AYA, Kobe City (JP); Yasutaka KOBAYASHI, Ogaki-shi (JP)

Correspondence Address: MOTS LAW, PLLC, 1629 K STREET N.W., SUITE 602, WASHINGTON, DC, 20006-1635, US

(73) Assignee: SANYO ELECTRIC CO., LTD., Moriguchi City (JP)

(21) Appl. No.: 12/406,153

(22) Filed: Mar. 18, 2009

(30) Foreign Application Priority Data
Mar. 19, 2008 (JP) JP2008-072490

(51) Int. Cl. H01L 21/3065; H01L 21/30

(52) U.S. Cl. 438/710; 438/758; 257/E21.218; 257/E21.211

(57) ABSTRACT

Provided is a semiconductor device manufacturing method by which plasma processing can be performed uniformly on a substrate. A plasma processing apparatus according to one embodiment of the present invention includes an auxiliary electrode provided annularly along a periphery of the lower electrode on a lateral side of the lower electrode. When plasma processing is performed on a substrate S, a potential of the lower electrode is set lower than the potential of the upper electrode while a potential of the auxiliary electrode is set lower than a potential of the upper electrode.

### CROSS REFERENCE TO RELATED APPLICATIONS

This application is based upon and claims the benefit of priority from prior Japanese Patent Application No. 200B-0724 90, filed on Mar. 19, 2008; the entire contents of which are incorporated herein by reference.

### BACKGROUND OF THE INVENTION

1. Field of the Invention

The present invention relates to a manufacturing method of a semiconductor device which includes a substrate.

2. Description of the Related Art

Conventionally, plasma processing apparatuses for performing plasma processing such as plasma CVD processing and plasma etching processing on a substrate have been broadly used in manufacturing steps of semiconductor devices. A plasma processing apparatus includes: a lower electrode including a placing face on which a substrate is placed; and an upper electrode facing the lower electrode while being located above the lower electrode. When plasma processing is performed on a substrate placed on the placing face, application of a voltage between the lower and upper electrodes generates plasma in a processing space provided between the lower and upper electrodes.

In order to uniformly perform the plasma processing on a substrate by use of the above-described plasma processing apparatus, it is desirable that uniform plasma be generated in the processing space. Accordingly, for the purpose of reducing non-uniformity of plasma in the processing space, there has been a proposal of providing, on a placing table, an annular member surrounding a periphery of a substrate (refer to Japanese Patent Application Laid-open Publication No. 2002-241946).

However, since the upper electrode is heated to a high temperature by being directly exposed to plasma, a central portion of the upper electrode is deformed into a shape that is convex downward. Accordingly, a distance between the upper and lower electrodes is changed during plasma processing, and a non-uniform electric field is formed in the processing space. As a result, uniform plasma cannot be generated in the processing space, whereby it has been difficult to uniformly perform plasma processing on a substrate. In particular, this problem has been more severe with a larger substrate.

### SUMMARY OF THE INVENTION

The present invention was made in consideration of the above-described problem, and an object thereof is to provide a manufacturing method of a semiconductor device by which plasma processing can be uniformly performed on a substrate.

A manufacturing method of a semiconductor device according to one aspect of the present invention is summarized as a manufacturing method of a semiconductor device including a substrate, the manufacturing method including the step of performing plasma processing on the substrate by using a plasma processing apparatus. In the method, the plasma processing apparatus includes: a first electrode including a placing face on which the substrate is placed; a flat plate-shaped second electrode provided so as to face the first electrode; and an auxiliary electrode provided annularly along a periphery of the first electrode on a lateral side of the first electrode, and, in the step of performing plasma processing: a potential of the first electrode is set lower than a potential of the flat plate-shaped second electrode; and a potential of the auxiliary electrode is set lower than the potential of the flat plate-shaped second electrode.

According to the manufacturing method of the semiconductor device of the one aspect of the present invention, even when a central portion of the upper electrode is deformed into a shape convex toward the lower electrode by having the upper electrode heated, an electric field intensity between an edge portion of the upper electrode and the lower electrode can be intensified. Therefore, electric field intensities in a processing space formed between the upper electrode and the lower electrode can be suppressed from becoming non-uniform. As a result, plasma can be uniformly generated in the processing space, whereby plasma processing can be uniformly performed on the substrate.

In the one aspect of the present invention, the first electrode and the flat plate-shaped second electrode may overlap each other on a projection plane substantially parallel to the placing table, the auxiliary electrode may be located outside the flat plate-shaped second electrode on the projection plane; and, in the step of performing plasma processing, the potential of the auxiliary electrode may be set lower than the potential of the first electrode.

In the one aspect of the present invention, the auxiliary electrode may be located inside the flat plate-shaped second electrode on a projection plane substantially parallel to the placing table; and, in the step of performing plasma processing, the potential of the auxiliary electrode is set higher than the potential of the first electrode.

According to the present invention, a semiconductor device manufacturing method by which plasma processing can be uniformly performed on a substrate can be provided.

### BRIEF DESCRIPTION OF THE DRAWINGS

FIG. 1 is a cross-sectional view of a plasma processing apparatus 100 according to a first embodiment of the present invention.

FIG. 2 is a projection view of a lower electrode 10, an upper electrode 20 and an auxiliary electrode 30 according to the first embodiment of the present invention.

FIG. 3 is a schematic view of a processing space I according to the first embodiment of the present invention.

FIG. 4 is a schematic view of the processing space I according to the first embodiment of the present invention.

FIG. 5 is a cross-sectional view of a plasma processing apparatus 200 according to a second embodiment of the present invention.

FIG. 6 is a projection view of the lower electrode 10, upper electrode 20 and auxiliary electrode 30 according to the second embodiment of the present invention.

FIG. 7 is a schematic view of the processing space I according to the second embodiment of the present invention.

FIG. 8 is a schematic view of the processing space I according to the second embodiment of the present invention.

FIG. 9 is a schematic view showing an electrode configuration of Comparative Example 1.

FIGS. 10A and 10B are view and graph, respectively, showing simulation results of Comparative Example 1.

FIG. 11 is a schematic view showing an electrode configuration of Example 1.

FIGS. 12A and 12B are view and graph, respectively, showing a simulation result of Example 1.

FIGS. 13A and 13B are view and graph, respectively, showing a simulation result of Example 2.

FIG. 14 is a schematic view showing an electrode configuration of Comparative Example 2.

FIGS. 15A and 15B are view and graph, respectively, showing a simulation result of Comparative Example 2.

FIG. 16 is a schematic view showing an electrode configuration of Example 3.

FIGS. 17A and 17B are view and graph, respectively, showing simulation results of Example 3.

FIGS. 18A and 18B are view and graph, respectively, showing simulation results of Example 4.

### DESCRIPTION OF THE PREFERRED EMBODIMENTS

Next, embodiments of the present invention will be described by use of the drawings. In the following description of the drawings, the same or corresponding elements are denoted with the same or corresponding reference numerals. However, the drawings are schematic, and it should be noted that proportions between dimensions and the like are not actual. Consequently, specific dimensions and the like should be determined in consideration of the following description. Additionally, it is obvious that the drawings include parts which differ in relations and proportions between the drawings.

### First Embodiment

### Configuration of Plasma Processing Apparatus

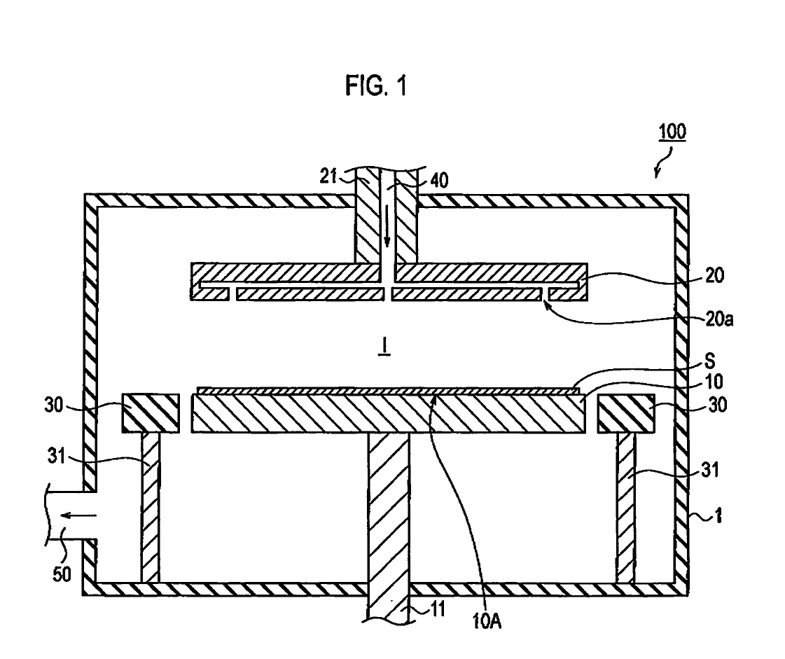

With reference to FIG. 1, a configuration of a plasma processing apparatus 100 according to a first embodiment of the present invention will be described. FIG. 1 is a cross-sectional view of the plasma processing apparatus 100.

In this embodiment, the plasma processing apparatus 100, which performs deposition processing on a substrate S by using a plasma enhanced chemical vapor deposition (PECVD) method, will be described as one example of plasma processing apparatuses.

The plasma processing apparatus 100 includes a vacuum chamber 1, a lower electrode 10, an upper electrode 20, an auxiliary electrode 30, a gas supply passage 40 and a gas discharge passage 50.

The vacuum chamber 1 is a processing container obtained by molding, for example, aluminum into a cylinder.

The lower electrode 10 functions as a placing table including a placing face 10A on which the substrate S is placed. The lower electrode 10 is supported by a support portion 11 so as to be vertically movable.

Additionally, the lower electrode 10 is connected to ground through the support portion 11, thereby functioning as an anode electrode. In an inside of the lower electrode 10, a heating mechanism (unillustrated) formed of, for example, molybdenum wire is provided. When plasma processing is performed on the substrate S, the lower electrode 10 is heated by the heating mechanism. The lower electrode 10 is formed of general electrically-conductive material such as carbon, graphite or aluminum.

The upper electrode 20 is provided over the lower electrode 10 so as to face the lower electrode 10. The upper electrode 20 is supported by the support portion 21 so as to be suspended from a ceiling of the vacuum chamber 1. Multiple gas supply openings 20a are formed in the upper electrode 20. Deposition gas and plasma-forming gas pass through a later-described gas supply passage 40, and are supplied to the inside of the vacuum chamber 1 from the plurality of gas supply openings 20a. Consequently, the upper electrode 20 functions as a gas supply mechanism.

Additionally, the upper electrode 20 functions as a cathode electrode if a direct-current voltage or a high-frequency voltage is applied, as a bias voltage, to the upper electrode 20 by use of an unillustrated power supply device. Consequently, a potential of the lower electrode 10 is lower than a potential of the upper electrode 20. Plasma is generated in a processing space I provided between the lower electrode 10 and the upper electrode 20 by applying a bias voltage to the upper electrode 20. The upper electrode 20 is formed of general electrically-conductive material such as carbon, graphite or aluminum.

An auxiliary electrode 30 is provided in a predetermined position relative to the lower electrode 10, the position being on the lateral side of the lower electrode 10. Additionally, the auxiliary electrode 30 is provided annularly along a periphery of the lower electrode 10.

Additionally, if a direct-current voltage or a high-frequency voltage is performed on the auxiliary electrode 30 by use of the unillustrated power supply device, a potential of the auxiliary electrode 30 becomes lower than the potential of the upper electrode 20. The auxiliary electrode 30 is formed of general electrically-conductive material such as carbon, graphite or aluminum.

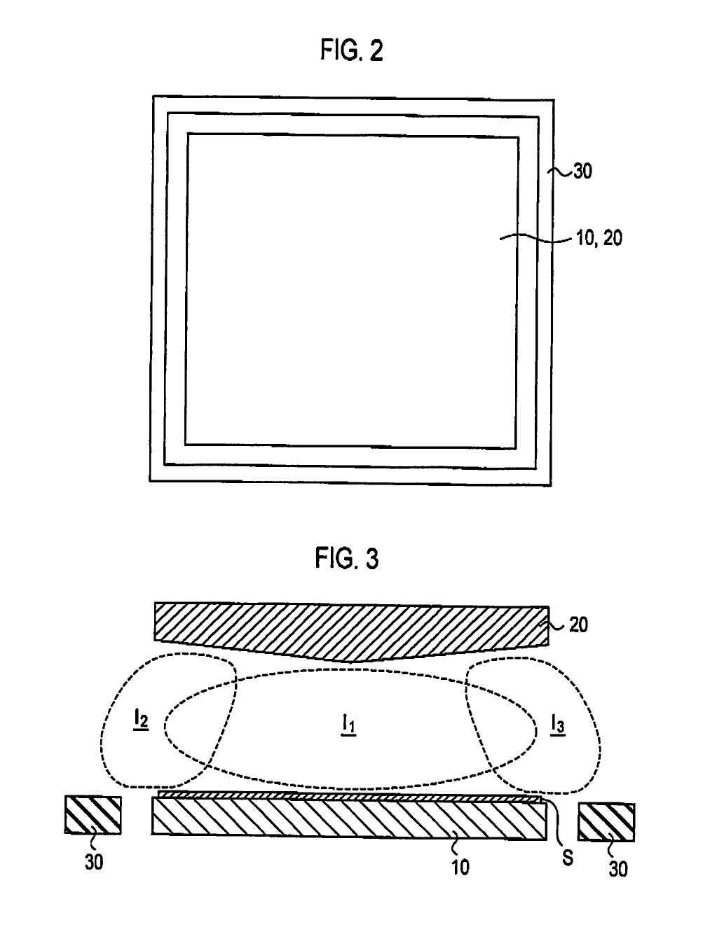

FIG. 2 is a projection view in which the lower electrode 10, the upper electrode 20 and the auxiliary electrode 30 are projected on a projection plane substantially parallel to the placing face 10A of the lower electrode 10. As shown in FIG. 2, planer shapes of the lower electrode 10 and the upper electrode 20 have substantially equal dimensions, whereby the lower electrode 10 and the upper electrode 20 overlap each other. The auxiliary electrode 30 surrounds peripheries of the lower electrode 10 and the upper electrode 20.

Note that planar shapes of the lower electrode 10, the upper electrode 20 and the auxiliary electrode 30 are not limited to rectangles, and may be round shapes or the like. Additionally, a cross-sectional shape of the auxiliary electrode 30 is not limited to a rectangle, and may be a round shape or a void shape.

The gas supply passage 40 is a gas supply tube used for supplying a deposition gas and a plasma-forming gas to the inside of the vacuum chamber 1. Although only one gas supply passage 40 is provided in FIG. 1, a gas supply passage supplying a deposition gas and a gas supply passage supplying a plasma-forming gas may be provided separately.

A gas discharge passage 50 is a gas discharge tube used for discharging gas in the vacuum chamber 1 so that interior of the vacuum chamber 1 becomes a vacuum.

### (Electric Fields Formed in Processing Space)

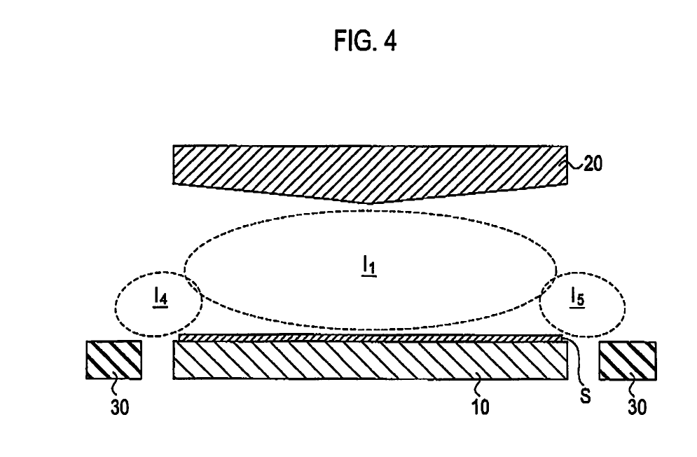

Next, electric fields formed in the processing space I will be described with reference to FIGS. 3 and 4. FIGS. 3 and 4 are schematic views of the processing space I. Note that FIGS. 3 and 4 show a state where a central portion of the upper electrode 20 is deformed into a shape convex toward the lower electrode 10 by having the upper electrode 20 heated to high temperature.

1) A Case where a Potential of the Auxiliary Electrode 30 is Lower than that of the Lower Electrode 10:

With reference to FIG. 3, a case where a potential of the auxiliary electrode 30 is lower than that of the lower electrode 10 will be described. A relationship among the lower electrode 10, the upper electrode 20 and the auxiliary electrode 30 in terms of potentials is the upper electrode 20>the lower electrode 10>the auxiliary electrode 30.

As shown in FIG. 3, when the central portion of the upper electrode 20 is deformed into a shape convex toward the lower electrode 10, a distance between the central portion of the upper electrode 20 and the lower electrode 10 becomes shorter. Here, a relationship indicated by expression (1) is established among an electric field intensity (E), a distance (L) between the upper electrode 20 and the lower electrode 10, and a voltage (V).

E∝(V/L) (1)

Consequently, an electric field intensity between an edge portion of the upper electrode 20 and the lower electrode 10 becomes relatively weak as compared to that between the central portion of the upper electrode 20 and the lower electrode 10.

If the potential of the auxiliary electrode 30 is set lower than those of the upper electrode 20 and the lower electrode 10 in this condition, a new electric field is formed between the auxiliary electrode 30 and the upper electrode 20. Between the auxiliary electrode 30 and the upper electrode 20, a strong electric field extending into space over the lower electrode 10 is formed. Specifically, electric field intensities in a processing space I₂ and processing space I₃ which are shown in FIG. 3 are intensified.

2) A Case where a Potential of the Auxiliary Electrode 30 is Higher than that of the Lower Electrode 10:

With reference to FIG. 4, a case where a potential of the auxiliary electrode 30 is higher than that of the lower electrode 10 will be described. A relationship among the lower electrode 10, the upper electrode 20 and the auxiliary electrode 30 in terms of potentials is the upper electrode 20>the auxiliary electrode 30>the lower electrode 10.

As has been described above, when the central portion of the upper electrode 20 is deformed into a shape convex toward the lower electrode 10, an electric field intensity between the edge portion of the upper electrode 20 and the lower electrode 10 becomes relatively weak as compared to that between the central portion of the upper electrode 20 and the lower electrode 10.

If the potential of the auxiliary electrode 30 is set lower than the upper electrode 20 and higher than the lower electrode 10 in this condition, a new electric field is formed between the auxiliary electrode 30 and the lower electrode 10. Specifically, electric field intensities in a processing space I₄ and processing space I₅ which are shown in FIG. 4 are intensified. Note that the electric field newly formed between the auxiliary electrode 30 and the lower electrode 10 concentrates between the auxiliary electrode 30 and an edge portion of the lower electrode 10.

### (Functions and Effects)

The plasma processing apparatus 100 according to this embodiment includes the auxiliary electrode 30 provided annularly along the periphery of the lower electrode 10 on the lateral side thereof. When plasma processing is performed on the substrate S, a potential of the lower electrode 10 is set lower than a potential of the upper electrode 20, and a potential of the auxiliary electrode 30 is set lower than the potential of the upper electrode 20.

Consequently, even when the central portion of the upper electrode 20 is deformed in a shape convex toward the lower electrode 10 by having the upper electrode 20 heated, an electric field intensity between the edge portion of the upper electrode 20 and the lower electrode 10 can be intensified. Therefore, electric field intensities in the processing space I can be suppressed from becoming non-uniform. As a result, plasma can be uniformly generated in the processing space I, whereby plasma processing can be uniformly performed on the substrate S.

Additionally, the potential of the auxiliary electrode 30 is set lower than the potential of the lower electrode 10 in a case where, the auxiliary electrode 30 is located outside the upper electrode 20 while the lower electrode 10 and the upper electrode 20 overlap each other on the projection plane substantially parallel to the placing face 10A.

In this case, a strong electric field extending into space over the lower electrode 10 can be formed between the auxiliary electrode 30 and the upper electrode 20. As a result, plasma can be more uniformly generated in the processing space I, whereby plasma processing can be more uniformly performed on the substrate S.

### Second Embodiment

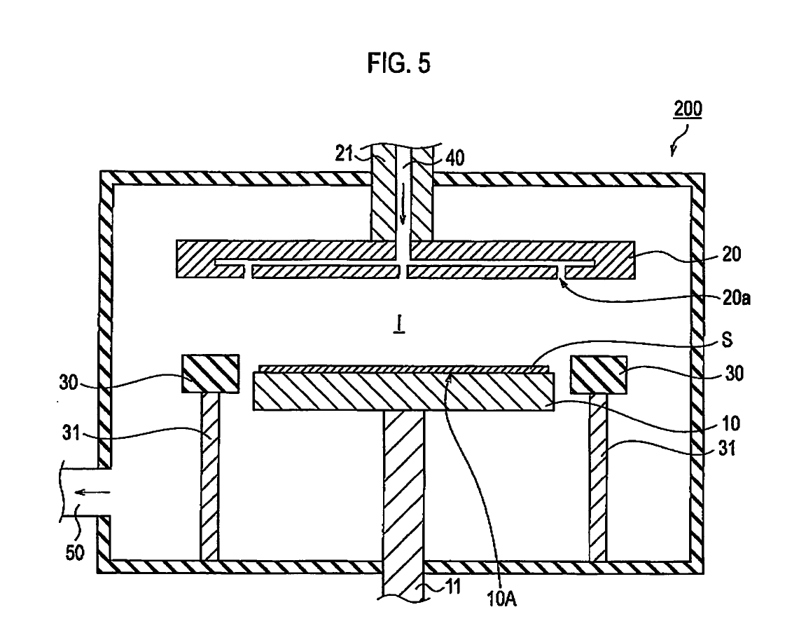

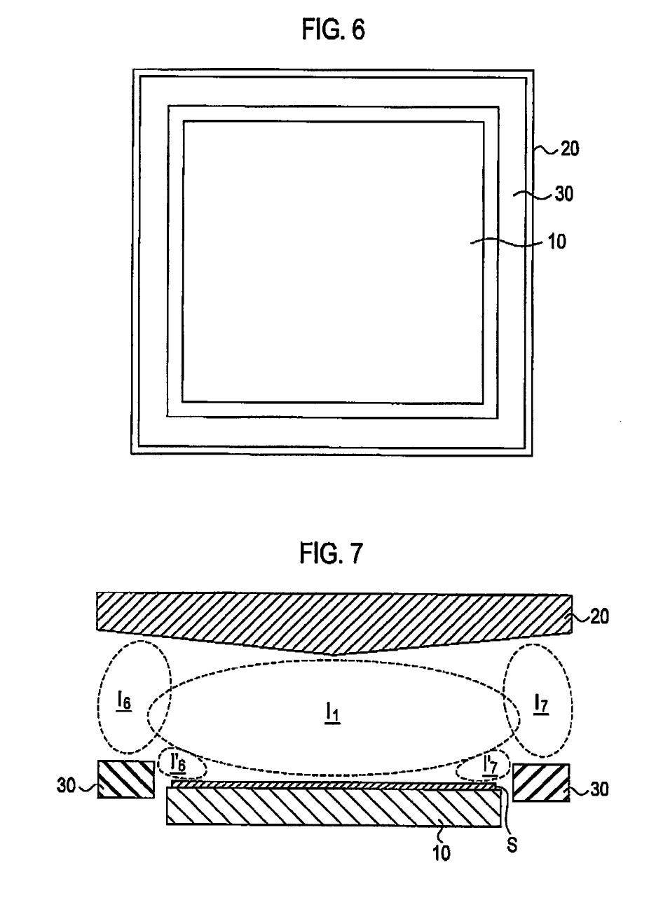

Next, a second embodiment of the present invention will be described with reference to FIGS. 5 and 6. FIG. 5 is a cross-sectional view of a plasma processing apparatus 200 according to this embodiment. FIG. 6 is a projection view in which the lower electrode 10, the upper electrode 20 and the auxiliary electrode 30 are projected on a projection plane substantially parallel to the placing face 10A of the lower electrode 10.

A difference between this embodiment and the above-mentioned first embodiment is in that the auxiliary electrode 30 is provided inside the upper electrode 20 on projection plane. Since there are no other differences therebetween, the above difference will be mainly described below.

### (Configuration of Plasma Processing Apparatus)

The lower electrode 10 functions as an anode electrode by being connected to ground through the support portion 11. The upper electrode 20 functions as a cathode electrode if a bias voltage is performed on the upper electrode 20. Consequently, a potential of the lower electrode 10 is lower than a potential of the upper electrode 20.

The auxiliary electrode 30 is provided in a predetermined relative to the lower electrode 10, the position being on the lateral side of the lower electrode 10. Additionally, the auxiliary electrode 30 is provided annularly along a periphery of the lower electrode 10.

As shown in FIG. 5, the lower electrode 10 and the auxiliary electrode 30 are located inside the upper electrode 20 on projection plane. The auxiliary electrode 30 surrounds the periphery of the lower electrode 10.

### (Electric Fields Formed in Processing Space)

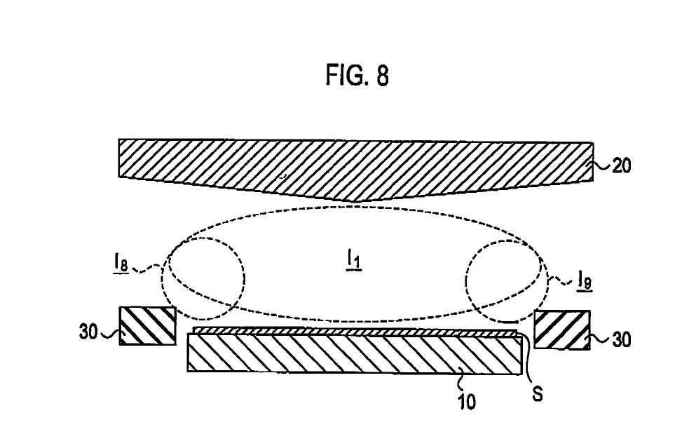

Next, electric fields formed in the processing space I will be described with reference to FIGS. 7 and 8. FIGS. 7 and 8 are schematic views of the processing space I. Note that FIGS. 7 and 8 show a state where a central portion of the upper electrode 20 is deformed into a shape convex toward the lower electrode 10 by having the upper electrode 20 heated.

1) A Case where a Potential of the Auxiliary Electrode 30 is Lower than that of the Lower Electrode 10:

With reference to FIG. 7, a case where a potential of the auxiliary electrode 30 is lower than that of the lower electrode 10 will be described. A relationship among the lower electrode 10, the upper electrode 20 and the auxiliary electrode 30 in terms of potentials is the upper electrode 20>the lower electrode 10>the auxiliary electrode 30.

As shown in FIG. 7, when the central portion of the upper electrode 20 is deformed into a shape convex toward the lower electrode 10, an electric field intensity between an edge portion of the upper electrode 20 and the lower electrode 10 becomes relatively weak as compared to that between the central portion of the upper electrode 20 and the lower electrode 10 in accordance with expression (1) mentioned above.

If the potential of the auxiliary electrode 30 is set lower than those of the upper electrode 20 and the lower electrode 10 in this condition, a new electric field is formed between the auxiliary electrode 30 and the upper electrode 20. Accordingly, electric field intensities in a processing space I₆ and processing space I₇ which are shown in FIG. 7 are intensified.

Note that, since an electric field directed from the lower electrode 10 toward the auxiliary electrode 30 is formed between the auxiliary electrode 30 and the lower electrode 10, electric field intensities in a processing space I₆′ and processing space I₇′ which are shown in FIG. 7 tends not to be intensified.

2) A Case where a Potential of the Auxiliary-Electrode 30 is Higher than that of the Lower Electrode 10:

With reference to FIG. 8, a case where a potential of the auxiliary electrode 30 is higher than that of the lower electrode 10 will be described. A relationship among the lower electrode 10, the upper electrode 20 and the auxiliary electrode 30 in terms of potentials is the upper electrode 20>the auxiliary electrode 30>the lower electrode 10.

As has been described above, when the central portion of the upper electrode 20 is deformed into a shape convex toward the lower electrode 10, an electric field intensity between the edge portion of the upper electrode 20 and the lower electrode 10 becomes relatively weak as compared to that between the central portion of the upper electrode 20 and the lower electrode 10.

When a potential of the auxiliary electrode 30 is set lower than the upper electrode 20 and higher than the lower electrode 10 in this condition, a new electric field directed from the auxiliary electrode 30 toward the lower electrode 10 is formed. Consequently, electric field intensities in processing space I₈ and processing space I₉ which are shown in FIG. 7 are intensified.

### (Functions and Effects)

By the plasma processing apparatus 200 according to this embodiment, an electric field intensity between the edge portion of the upper electrode 20 and the lower electrode 10 can be intensified as in the case of the plasma processing apparatus 100 according to the above-mentioned first embodiment. Therefore, electric field intensities in the processing space I can be suppressed from being non-uniform. As a result, plasma can be uniformly generated in the processing space I, whereby plasma processing can be uniformly performed on the substrate S.

Additionally, a potential of the auxiliary electrode 30 is set higher than a potential of the lower electrode 10 in a case where the auxiliary electrode 30 is located inside the upper electrode 20 on the projection plane substantially parallel to the placing face 10A.

In this case, an electric field directed from the auxiliary electrode 30 to the lower electrode 10 can be formed. As a result, plasma can be more uniformly generated in the processing space I, whereby plasma processing can be more uniformly performed on the substrate S.

### Other Embodiments

While the present invention has been described through the abovementioned embodiments, discussions and drawings, which constitute parts of this disclosure, should not be understood as limiting this invention. Through this disclosure, various alternative embodiments, examples and operational technologies will be apparent to those skilled in the art.

For example, in the above embodiments, while description has been given to the cases where deposition processing is performed on the substrate S by using the plasma processing apparatuses 100 and 200, other plasma processing such as plasma etching processing may be performed by the plasma processing apparatuses 100 and 200.

Additionally, while a potential of the lower electrode 10 is set to a ground potential in the above-mentioned embodiments by having the lower electrode 10 connected to the ground, it is only necessary that a potential of the lower electrode 10 be lower than that of the upper electrode 20.

Additionally, while levels of the lower electrode 10 and the auxiliary electrode 30 are set equal to each other in the abovementioned first embodiment, levels of the lower electrode 10 and the auxiliary electrode 30 may be different from each other. Likewise, while the auxiliary electrode 30 is provided in a position higher than the lower electrode 10 in the abovementioned second embodiment, the auxiliary electrode 30 may be provided in a position lower than the lower electrode 10.

Additionally, while the auxiliary electrode 30 is fixed to the inside of the vacuum chamber 1 through a support portion 31 in the abovementioned embodiments, the auxiliary electrode 30 may be supported so as to be vertically movable.

Additionally, while the lower electrode 10 and the upper electrode 20 have been described as examples of a first electrode and a second electrode of the present invention, respectively, in the abovementioned embodiments, arrangement of the first electrode and the second electrode is not limited to the above arrangement. That is, the first electrode and the second electrode may be set standing substantially vertically to a horizontal face, or the first electrode may be arranged over the second electrode.

### (Electric Field Intensities Simulations)

Next, description will be given of simulative measurement which was carried out with respect to electric field intensities in the processing space I by use of a publicly available two-dimensional electric field simulator (retrieved on Mar. 10, 2008 through URL: http://www.ansoft.com).

### Comparative Example 1

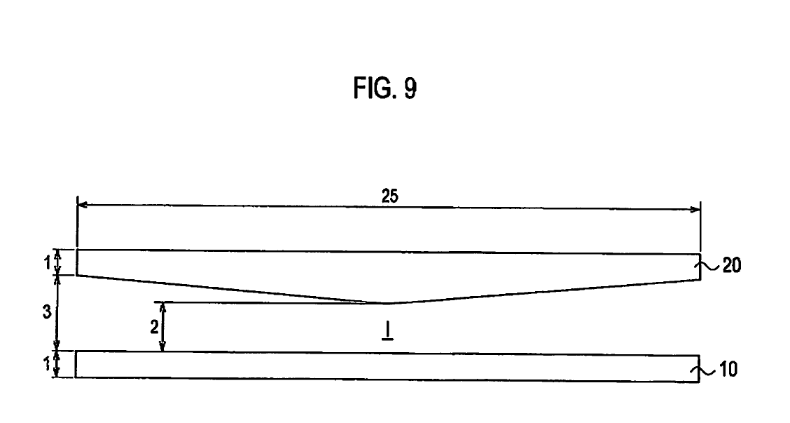

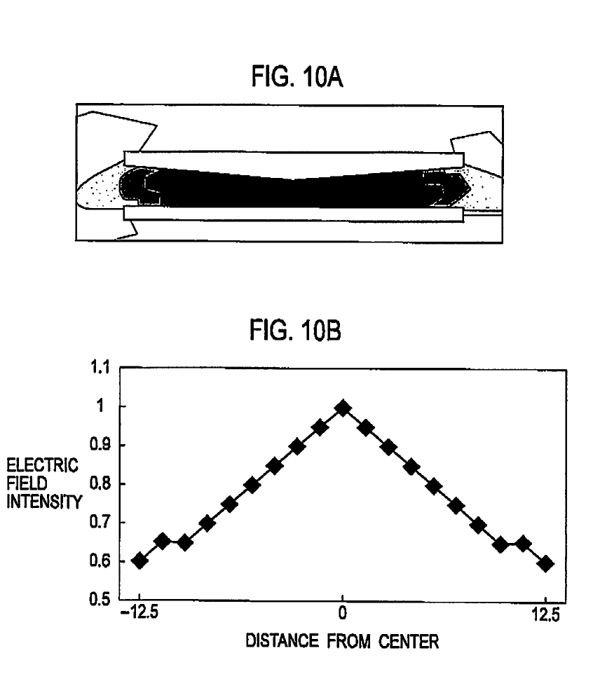

An electrode configuration according to Comparative Example 1 is schematically shown in FIG. 9. A simulation result in a case where standardized voltage values of the lower electrode 10 and the upper electrode 20 were set to 0 and +100, respectively, in the configuration shown in FIG. 9 is shown in FIGS. 10A and 10B.

FIG. 10A is a schematic view of an electric field formed in the processing space I. FIG. 10B is a graph showing a relationship between a standardized electric field intensity value in the processing space I and a distance from the center of the processing space I.

### Example 1

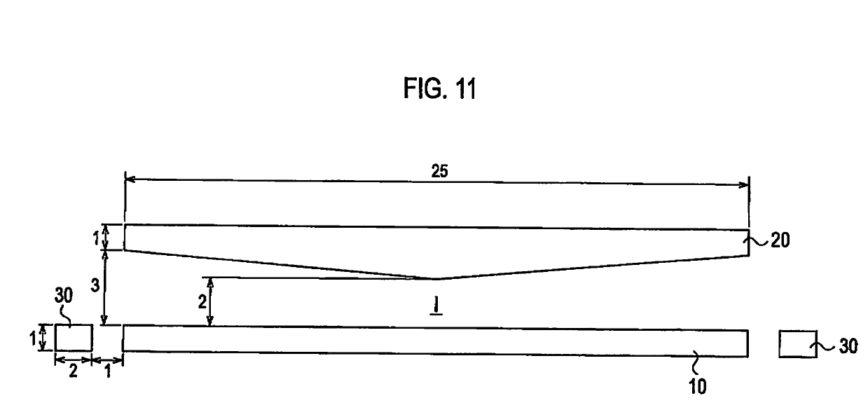

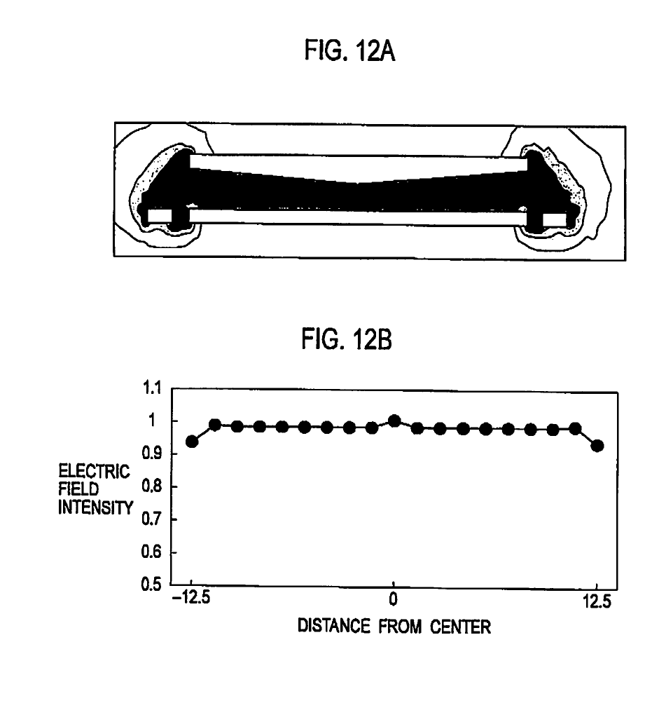

An electrode configuration according to Example 1 is schematically shown in FIG. 11. A simulation result in a case where standardized voltage values of the lower electrode 10, the upper electrode 20 and the auxiliary electrode 30 were set to 0, +100 and −50, respectively, in the configuration shown in FIG. 11 is shown in FIGS. 12A and 12B.

### Example 2

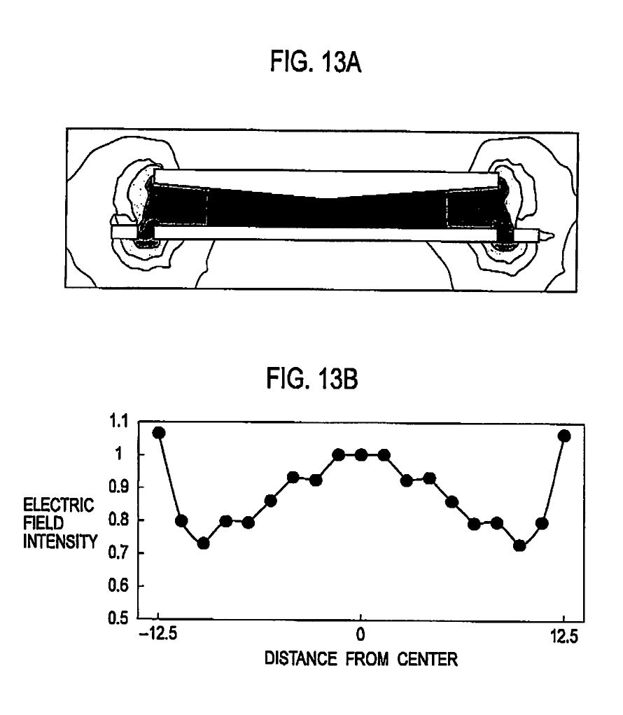

An electrode configuration according to Example 2 is the same as one shown in FIG. 11. A simulation result in a case where standardized voltage values of the lower electrode 10, the upper electrode 20 and the auxiliary electrode 30 were set to 0, +100 and +50, respectively, in the configuration shown in FIG. 11 is shown in FIGS. 13A and 13B.

### Comparative Example 2

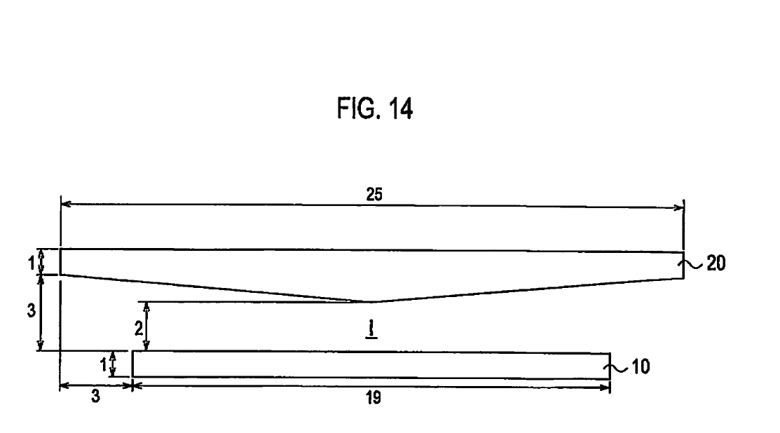

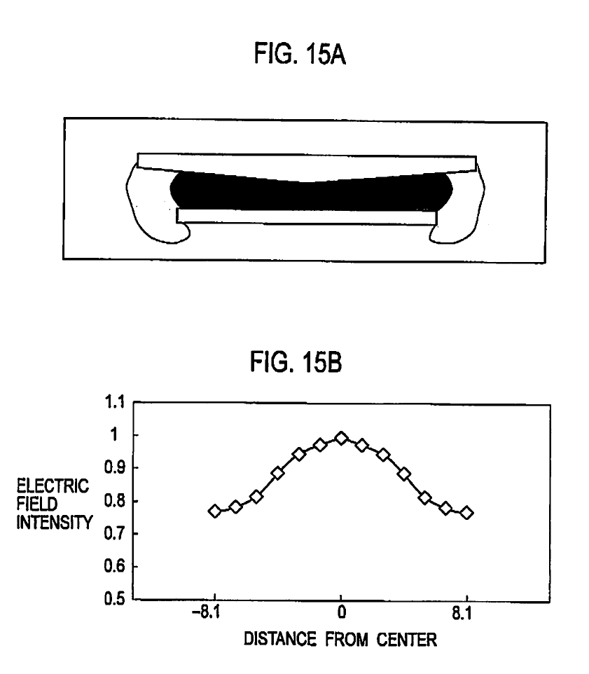

An electrode configuration according to Comparative Example 2 is schematically shown in FIG. 14. A simulation result in a case where standardized voltage values of the lower electrode 10 and the upper electrode 20 were set to 0 and +100, respectively, in the configuration shown in FIG. 14 is shown in FIGS. 15A and 15B.

FIG. 15A is a schematic view of an electric field formed in the processing space I. FIG. 15B is a graph showing a relationship between a standardized electric field intensity value in the processing space I and a distance from the center of the processing space I.

### Example 3

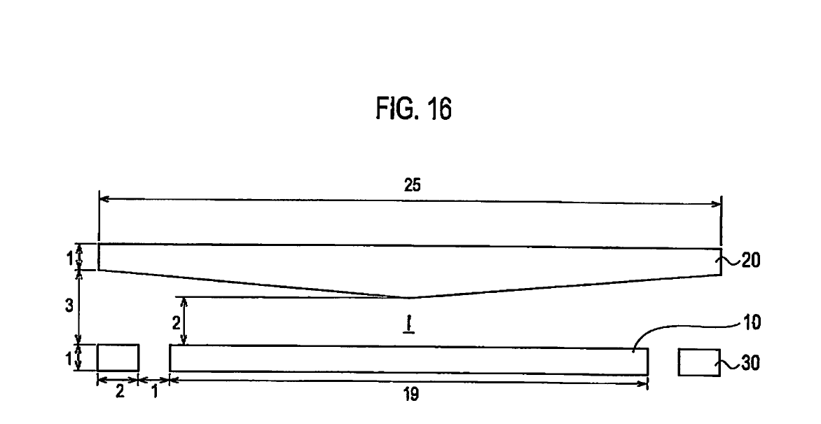

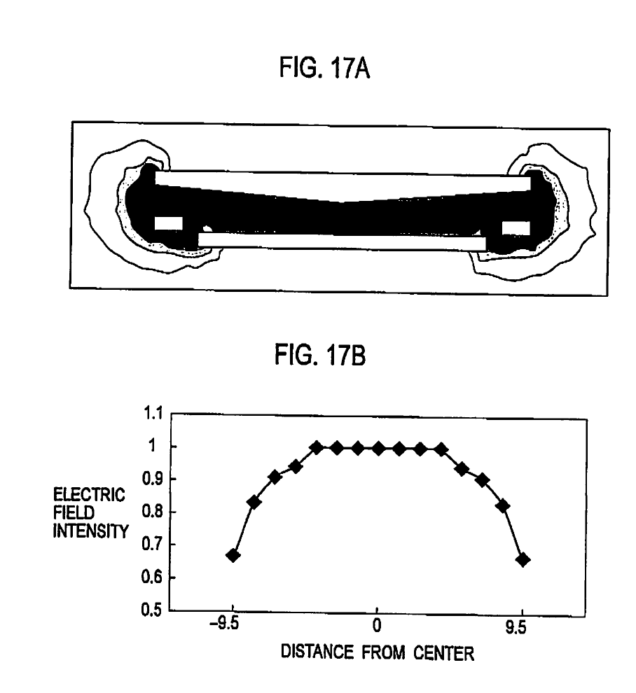

An electrode configuration according to Example 3 is schematically shown in FIG. 16. A simulation result in a case where standardized voltage values of the lower electrode 10, the upper electrode 20 and the auxiliary electrode 30 were set to 0, +100 and −80, respectively, in the configuration shown in FIG. 16 is shown in FIGS. 17A and 17B.

### Example 4

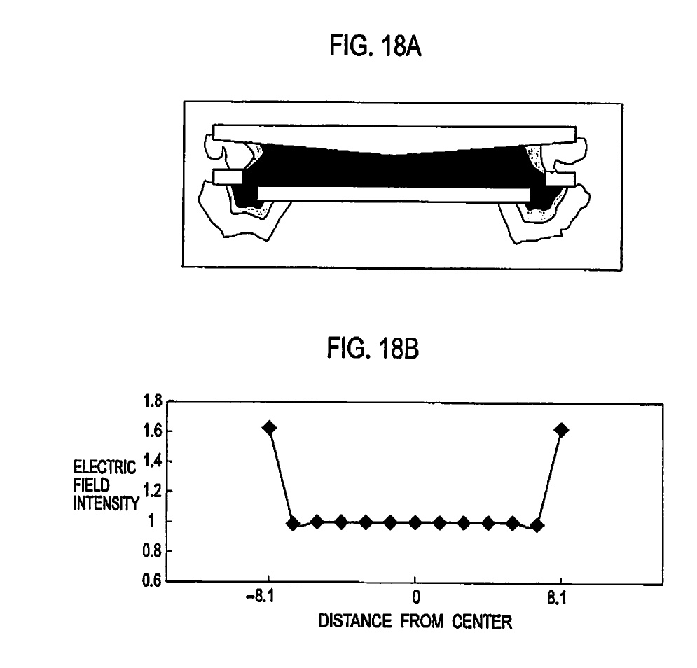

An electrode configuration according to Example 4 is the same as one shown in FIG. 16. A simulation result in a case where standardized voltage values of the lower electrode 10, the upper electrode 20 and the auxiliary electrode 30 were set to 0, +100 and +80, respectively, in the configuration shown in FIG. 16 is shown in FIGS. 18A and 18B.

### (Consideration)

Examples 1 and 2 were capable of forming more uniform electric fields than Comparative Example 1. This is because each of Examples 1 and 2 was capable of intensifying electric fields in an edge portion of the processing space I by being provided with the auxiliary electrode 30.

Additionally, Example 1 was capable of forming a more uniform electric field than Example 2. This is because, while electric field intensities in the processing space I₂ and the processing space I₃ which are shown in FIG. 3 were intensified in Example 1, a new electric field was locally formed around an edge portion of the lower electrode 10 in Example 2. Based on these results, it was confirmed that, in a case where the auxiliary electrode 30 is located outside the upper electrode 20 on the projection plane, it is preferable that a potential of the auxiliary electrode 30 be lower than a potential of the lower electrode 10.

On the other hand, Examples 3 and 4 were capable of forming more uniform electric fields than Comparative Example 2. This is because provision of the auxiliary electrode 30 made it possible to intensify an electric field in an edge portion of the processing space I.

Additionally, Example 4 was capable of forming a more uniform electric field than Example 3. This is because, while an electric field directed from the auxiliary electrode 30 toward the lower electrode 10 was formed in Example 4, an electric field directed from the lower electrode 10 toward the auxiliary electrode 30 was formed in Example 3. It was therefore hard for electric field intensities in the processing space Id and the processing space I₇′ which are shown in FIG. 7 to be intensified in Example 3. Based on these results, it was confirmed that, in a case where the auxiliary electrode 30 is located inside the upper electrode 20 on the projection plane, it is preferable that a potential of the auxiliary electrode 30 be higher than a potential of the lower electrode 10.

What is claimed is:

1. A manufacturing method of a semiconductor device which includes a substrate, comprising the step of performing plasma processing on the substrate by using a plasma processing apparatus, wherein:
the plasma processing apparatus includes:
a first electrode including a placing face on which the substrate is placed;
a flat plate-shaped second electrode provided so as to face the first electrode; and
an auxiliary electrode provided annularly along a periphery of the first electrode on a lateral side of the first electrode, and
in the step of performing plasma processing,
a potential of the first electrode is set lower than a potential of the flat plate-shaped second electrode, and
a potential of the auxiliary electrode is set lower than the potential of the flat plate-shaped second electrode.

2. The manufacturing method of a semiconductor device according to claim 1, wherein
the first electrode and the flat plate-shaped second electrode overlap each other on a projection plane substantially parallel to the placing table,
the auxiliary electrode is located outside the flat plate-shaped second electrode on the projection plane, and
in the step of performing plasma processing, the potential of the auxiliary electrode is set lower than the potential of the first electrode.

3. The manufacturing method of a semiconductor device according to claim 1, wherein
the auxiliary electrode is located inside the flat plate-shaped second electrode on a projection plane substantially parallel to the placing table, and
in the step of performing plasma processing, the potential of the auxiliary electrode is set higher than the potential of the first electrode.
